(19) United States
(12) Patent Application Publication
(10) Pub. No.: US 2013/0229215 A1
(43) Pub. Date: Sep. 5, 2013

(54) Variable Resistance for Driver Circuit Dithering

(71) Applicant: Laurence P. Sadwick, Salt Lake City, UT (US)

(72) Inventor: Laurence P. Sadwick, Salt Lake City, UT (US)

(21) Appl. No.: 13/783,479

(22) Filed: Mar. 4, 2013

Related U.S. Application Data
(60) Provisional application No. 61/606,286, filed on Mar. 2, 2012.

(51) Int. Cl. H03K 3/84

(52) U.S. Cl. CPC H03K 3/84
USPC 327/164

(57) ABSTRACT

A dither circuit yielding a variable resistance.

### CROSS REFERENCE TO RELATED APPLICATIONS

The present application claims priority to U.S. Patent Application No. 61/606,286 entitled “Variable Resistance for Driver Circuit Dithering”, filed Mar. 2, 2012, the entirety of which is incorporated herein by reference for all purposes.

### BACKGROUND

Electronic circuits such as power supplies and drivers are widely used to power and control electrical circuits and devices such as lighting circuits with light emitting diodes (LEDs) and light dimming circuits. However, switching elements in power supplies and drivers can cause electromagnetic interference (EMI), causing problems for nearby electrical devices. Such switching elements can also reduce the efficiency and power factor of electrical circuits.

### SUMMARY

A dithering circuit is disclosed which may be used for example to vary a control resistance used to set the frequency and/or duty cycle of a switching circuit, such as a switching circuit in a power supply, a switching circuit in an LED driver, a clock, essentially any circuit that uses a timing resistor, etc. An example LED driver that benefits from a dithering circuit provides power for LED lighting systems using pulse control of a switch to adjust load current and/or voltage. The LED driver sets the frequency of the pulse signal used to control the switch based on an impedance value set by an external resistor. The dithering circuit may be used in place of or in conjunction with the external resistor to vary the frequency of the pulse signal, spreading the frequency of the noise or EMI generated by the switch and reducing its affects.

This summary provides only a general outline of some particular embodiments. Many other objects, features, advantages and other embodiments will become more fully apparent from the following detailed description.

### BRIEF DESCRIPTION OF THE DRAWINGS

A further understanding of the various embodiments may be realized by reference to the figures which are described in remaining portions of the specification. In the figures, like reference numerals may be used throughout several drawings to refer to similar components.

FIG. 1 depicts a block diagram of a dimming driver with a dither circuit in accordance with some embodiments of the invention;

FIG. 2 depicts a schematic of a dimming driver with a dither circuit in accordance with some embodiments of the invention;

FIG. 3 depicts a schematic of a variable resistance circuit that may be used as a dither circuit in accordance with some embodiments of the invention;

FIG. 4 depicts a graph of a reference current generated at the input of a current mirror in the variable resistance circuit of FIG. 3;

FIG. 5 depicts a schematic of a variable resistance circuit that may be used as a dither circuit in accordance with some embodiments of the invention, with a voltage source illustrating the connection of a frequency control device;

FIG. 6 depicts a graph of a reference current generated at the output of the variable resistance circuit of FIG. 5 with a first voltage level generated by the frequency control device;

FIG. 7 depicts a graph of a current generated at the output of the variable resistance circuit of FIG. 5 with a second voltage level generated by the frequency control device;

FIG. 8 depicts a schematic of a variable resistance circuit that may be used as a dither circuit and connected in parallel with a frequency control resistor, and depicting a test resistor and voltage source illustrating the connection of a frequency control device;

FIG. 9 depicts a graph of the current across the frequency control resistor of FIG. 8;

FIG. 10 depicts a graph of the total current through the frequency control device, including the reference current from the variable resistance circuit and the current across the frequency control resistor of FIG. 8;

FIG. 11 depicts a dither circuit including a waveform source and current mirror, connected to a frequency control device in parallel with a frequency control resistor;

FIG. 12 depicts a dither circuit including a waveform source and current mirror, connected to a frequency control device in series with a frequency control resistor;

FIG. 13 depicts a dither circuit including a waveform source and current mirror, connected to a pulse generator used to control a power control switch;

FIG. 14 depicts a graph of the current through the power control switch of FIG. 13, illustrating the frequency variation caused by the dither circuit;

FIG. 15 depicts a NAND-based pulse generator connected to a dither circuit, with a voltage source representing a frequency control device;

FIG. 16 depicts an inverter-based pulse generator connected to a dither circuit, with a voltage source representing a frequency control device; and

FIG. 17 depicts a graph of the current through the frequency control device of FIGS. 15 and 16.

### DESCRIPTION

A dithering circuit is disclosed which may be used for example to vary a control resistance to set the frequency and/or duty cycle of a switching circuit in a power supply, for example, an LED driver, a fluorescent lamp driver, a general lighting driver, a current or voltage controlled power supply, etc. An example LED driver that benefits from a dithering circuit provides power for LED lighting systems using pulse control of a switch to adjust load current and/or voltage. The LED driver sets the frequency of the pulse signal used to control the switch based on an impedance value set by an external resistor which is sometimes referred to, in general, as a timing or frequency resistor. The dithering circuit may be used in place of or in conjunction with the external resistor to vary the frequency of the pulse signal, spreading the frequency of the noise or EMI generated by the switch and reducing its affects.

Examples of LED drivers that may incorporate a dithering circuit disclosed herein include those in U.S. patent application Ser. No. 12/422,258, filed Apr. 11, 2009 for a “Dimmable Power Supply”, and in U.S. patent application Ser. No. 12/776,409, filed May 9, 2010 for a “LED Lamp with Remote Control”, which are incorporated herein by reference for all purposes. Such a driver provides power for lights such as LEDs of any type and other loads. The lighting driver may be dimmed or otherwise controlled externally, for example by controlling a line voltage supplying the lighting driver, or internally, for example using a wireless controller to command internal dimming circuits, etc. The current and/or voltage to a load is adjusted using a switch to pass or block input current, controlled by a variable pulse signal.

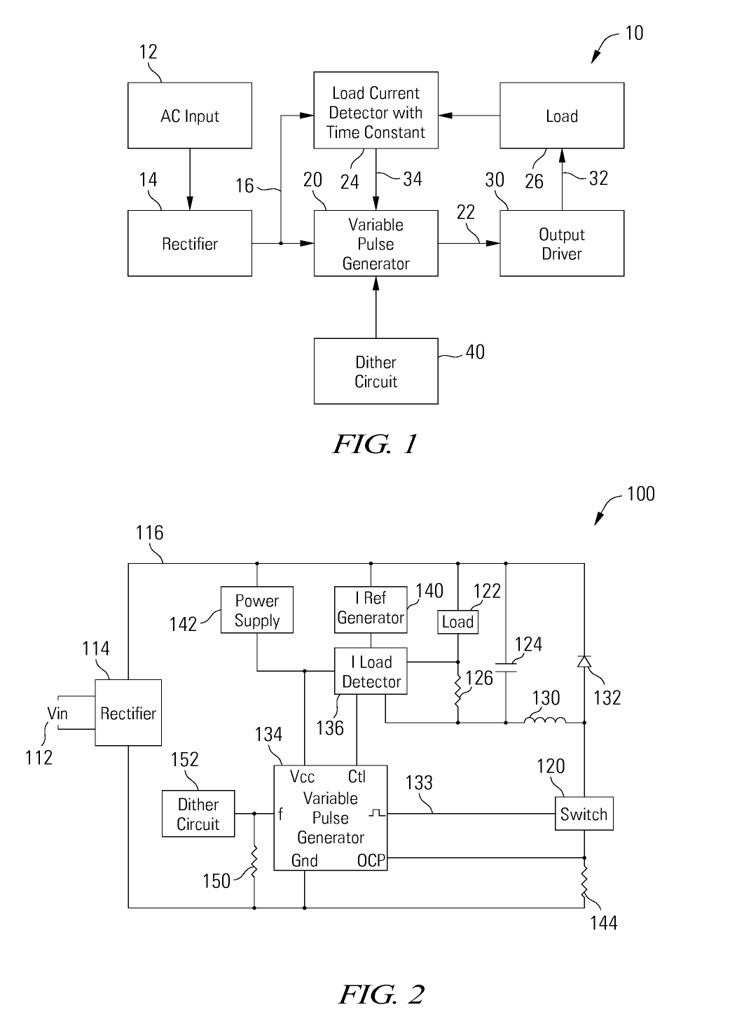

Turning to FIG. 1, a block diagram of a dimming driver with a dither circuit in accordance with some embodiments of the invention. The dimming driver with dither circuit 10 is powered in some embodiments by an AC input 12, for example by a 50 or 60 Hz sinusoidal waveform of 120 V or 240 V RMS or higher such as that supplied to commercial and residential facilities by municipal electric power companies. The dimming driver can also be supplied with a direct current (DC) voltage/current/power supply. It is important to note, however, that the dimming driver with dither circuit 10 is not limited to any particular power input. Furthermore, the voltage applied to the AC input 12 may be externally controlled, such as in an external dimmer (not shown) that reduces the voltage. The AC input 12 is connected to a rectifier 14 to rectify and invert any negative voltage component from the AC input 12. Although the rectifier 14 may filter and smooth the power output 16 if desired to produce a DC signal, this is not necessary and the power output 16 may be a series of rectified half sinusoidal waves at a frequency double that at the AC input 12, for example 100 or 120 Hz. A variable pulse generator 20 is powered by the power output 16 from the AC input 12 and rectifier 14 to generate a train of pulses at output 22. The pulse width of the pulses in output 22 is controlled in the variable pulse generator 22 by load current detector 24 based on load current levels. Various implementations of pulse width control including pulse width modulation (PWM) by frequency, analog and/or digital control may be used to realize the pulse width control. Other features such as soft start, delayed start, instant on operation, etc. may also be included if deemed desirable, needed, and/or useful. Output driver 30 produces a current through the load 26, with the current levels adjusted by the pulse width at the output 22 variable pulse generator 22. The load current is monitored by the load current detector 24 and may also be monitored by a master load current detector sensor. Such a sensor may be, but is not limited to, a sense resistor, a sense transformer, a winding on a transformer or inductor, sensing via passive and/or active components, etc.

A dither circuit 40 is provided to vary the frequency and/or duty cycle of the variable pulse generator 20, spreading noise such as EMI from the dimming driver with dither circuit 10 over a wider range of frequencies to reduce its effect. Less noise is generated at the original non-dithered frequency, because the circuit operation is shifted across the dithered range of spread frequencies and spends less time operating at the non-dithered frequency or at any single frequency. The term “dither” is used herein to refer to variation in the frequency and/or duty cycle of the output of the pulse generator, which may be random, pseudo-random, or have any other shifting variation.

Turning to FIG. 2, a schematic of an embodiment of a dimming driver with dither circuit 100 is illustrated in accordance with some embodiments of the invention. An AC input 112 is converted to a DC supply 116 by rectifier 114. As noted above, the dimming driver with dither circuit 100 is not limited to this particular example power configuration. A switch 120 controls current from DC supply 116 to a load 122. The load 122 is connected in parallel with, for example, a capacitor 124 which is optional in some embodiments of the present invention. An optional load current sense resistor 126 can be connected in series with the load 122. An inductor 130 is connected in series with load 122 and capacitor 124 to store energy as current flows from DC supply 116 through the load 122, when the switch 120 is on. A diode 132 is connected to make a loop including load 122 and inductor 130, allowing energy stored in inductor 130 to produce a current through load 122 when switch 120 is off.

The switch 120 is controlled by pulses at an output 133 of a variable pulse generator 134. The on-time and/or off-time of the pulses from the variable pulse generator 134 may be adjusted based on the current through the load 122, measured by load current detector 136 based on load current sense resistor 126. The dimming driver with dither circuit 100 may be dimmed by an external dimmer, controlled by the voltage level at DC supply 116 as represented by a reference current from a reference current generator 140. The dimming driver with dither circuit 100 may also be dimmed by an internal dimmer that adjusts the reference current from reference current generator 140 based on any suitable control input. The on-time and/or off-time of the pulses from the variable pulse generator 134 may be also be adjusted based on the input current through the switch 120, measured for example using a current sense resistor 144.

Components of the dimming driver with dither circuit 100 may be powered by any suitable power source, such as from the DC supply 116 via a power supply 142.

The frequency of the pulses at the output 133 of the variable pulse generator 134 is set in some embodiments by a resistor 150, with the variable pulse generator 134 applying a test voltage to the resistor 150 and basing the frequency on the current through the resistor 150. A dither circuit 152 is used in conjunction with or to replace the resistor 150, varying the resistance to dither the frequency of the pulses at output 133 of variable pulse generator 134.

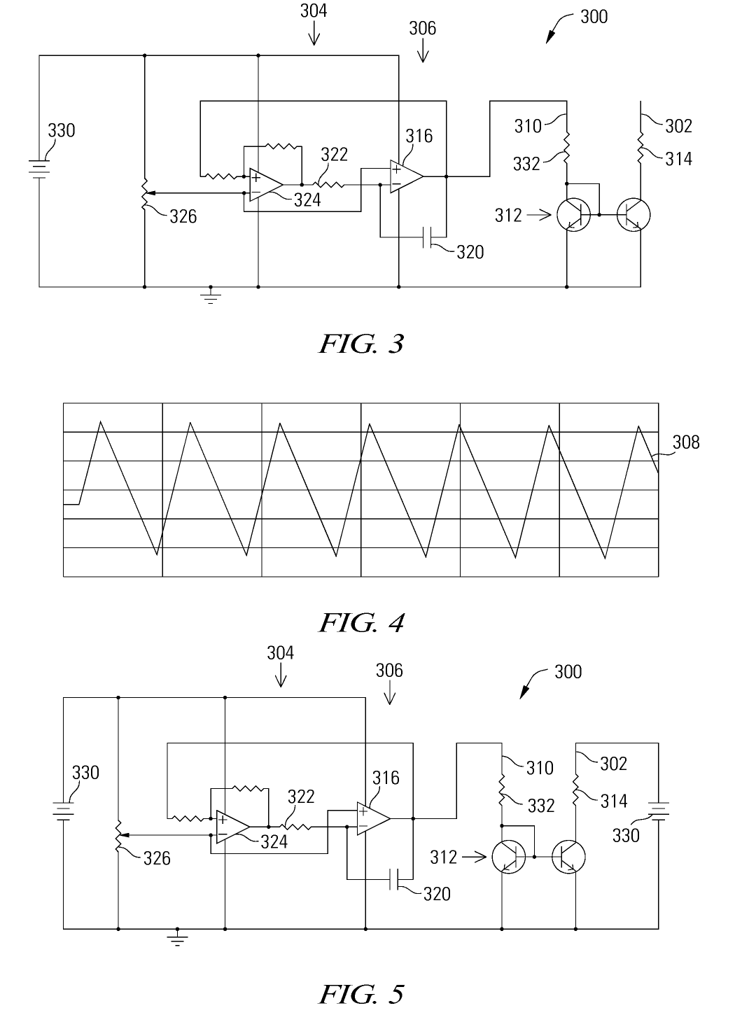

Turning to FIG. 3, a dither circuit 300 produces a variable resistance at an output 302. An integrator 306 and comparator 304 produce a triangle wave or sawtooth wave 308 such as that illustrated in FIG. 4 at the input 310 to a current mirror 312. The integrator 306 includes an op-amp 316 with a feedback capacitor 320 and resistor 322 connected to the inverting input, forming an RC network. The capacitor 320 is charged and discharged over time, depending on whether the signal applied to the resistor 322 is high or low. Notably, any other suitable circuit may be used in place of the integrator 306 to produce a triangle wave or sawtooth wave, and other embodiments perform dithering in other manners than the triangle wave or sawtooth wave. The comparator 304, based on op-amp 324, toggles the state of the signal applied to resistor 322 by comparing the output of op-amp 316 in integrator 306 with a reference voltage provided by a potentiometer 326, or a voltage divider or other variable impedance or other voltage source. When the output of op-amp 316 in integrator 306 with a reference voltage rises to a level established by reference source 326, the comparator 304 turns off the signal applied to resistor 322 and the waveform 308 begins to fall. When the output of op-amp 316 in integrator 306 with a reference voltage falls to a level established by reference source 326, the comparator 304 turns on the signal applied to resistor 322 and the waveform 308 begins to rise.

Current mirror 312 controls the current through resistor 314, used to set the effective impedance of the frequency input (also referred to herein as an impedance input) to the pulse generator (e.g., 134). Resistor 314 may be connected alone to the frequency input of the pulse generator (e.g., 134), or in parallel or in series with an external resistor (e.g., 150) connected to the frequency input of the pulse generator (e.g., 134). The current from the output of op-amp 316 in integrator 306 through resistor 332 and the diode-connected transistor of current mirror 312 controls the current through resistor 314 at dither circuit output 302.

The dither circuit 300 may be powered by any suitable power supply 330, such as a power supply (e.g., 142) that derives power from DC supply 116 or AC input 112. In other embodiments, the dither circuit 300 is powered by other sources such as a tag-along inductor coupled to inductor 130, a battery, solar power source, mechanical or thermal power source, etc, or any combination of these, etc.

The dither circuit 300 can be used to modulate the current used for example to set the frequency of variable pulse generator 134 in dimming driver with dither circuit 100, without interfering with the voltage level applied by the variable pulse generator 134. The resistor 314 may be used in place of resistor 150 of dimming driver with dither circuit 100, or may be connected in series or in parallel or in other combinations with resistor 150.

The dither circuit 300 may be adapted to generate any desired waveform, including single or multiple, simple or complex waveforms, or random or pseudo-random waveforms. The current mirror 312 and other components of the dither circuit 300 is not limited to bipolar junction transistors (BJTs) but may comprise N-channel metal oxide semiconductor field effect transistors (MOSFETs), P-Channel MOSFETs, NPN bipolar junction transistors (BJTs), PNP BJTs, junction FETs, heterojunction bipolar transistors (HBTs), high electron mobility transistors (HEMTs), modulation doped transistors (MODFETs), any other type of transistor, appropriate three terminal devices, op amps, etc. The dither circuit 300 and transistors therein can be made of any material or materials including, but not limited to, silicon (Si), silicon carbide (SiC), silicon germanium (SiGe), gallium arsenide (GaAs)-based, gallium nitride (GaN)-based, indium phosphide (InP)-based, silicon on insulator (SOI), any combination of binary, ternary, etc. compounds, etc. The dither circuit 300 may be made or incorporated into an integrated circuit, and can be made of discrete or integrated components.

Various embodiments of a dither circuit may be used to generate any suitable current waveform, using any suitable technique. For example, a digital to analog converter (DAC) may be used to generate a current waveform. Single or multiple waveforms may be used and may be summed, multiplied, divided, added, subtracted, etc. in the time, frequency, amplitude, etc. domains. The dither circuit 300 may be used at any practical frequency—low or high. The dither circuit 300 may yield a waveform at a single frequency or at multiple frequencies, with constant or varying frequencies.

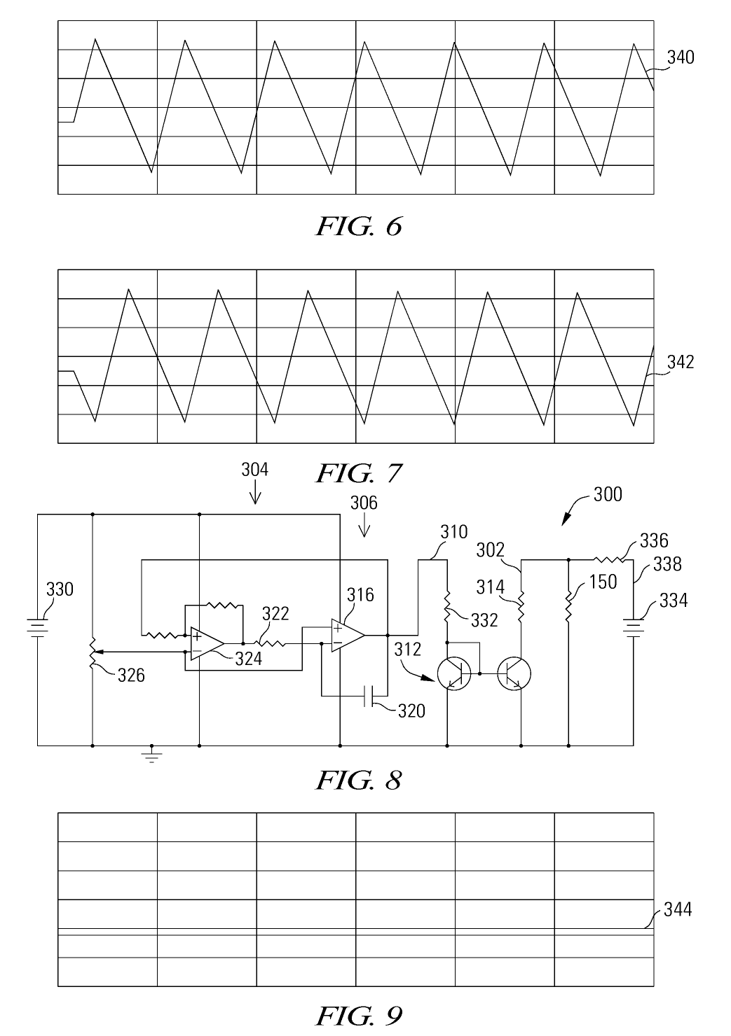

Turning to FIG. 5, the dither circuit 300 is depicted with a voltage source 330 representing or illustrating the connection of a frequency control device, such as the frequency setting component of variable pulse generator 134. The voltage source 330 represents the voltage applied by variable pulse generator 134 to resistor 150 and/or dither circuit 300. The current waveforms 340, 342 illustrated in FIGS. 6 and 7 are generated using two different voltages from voltage source 330, demonstrating the substantially voltage-independent current modulation. The current waveforms of FIGS. 6 and 7 are measured at output 302 of dither circuit 300.

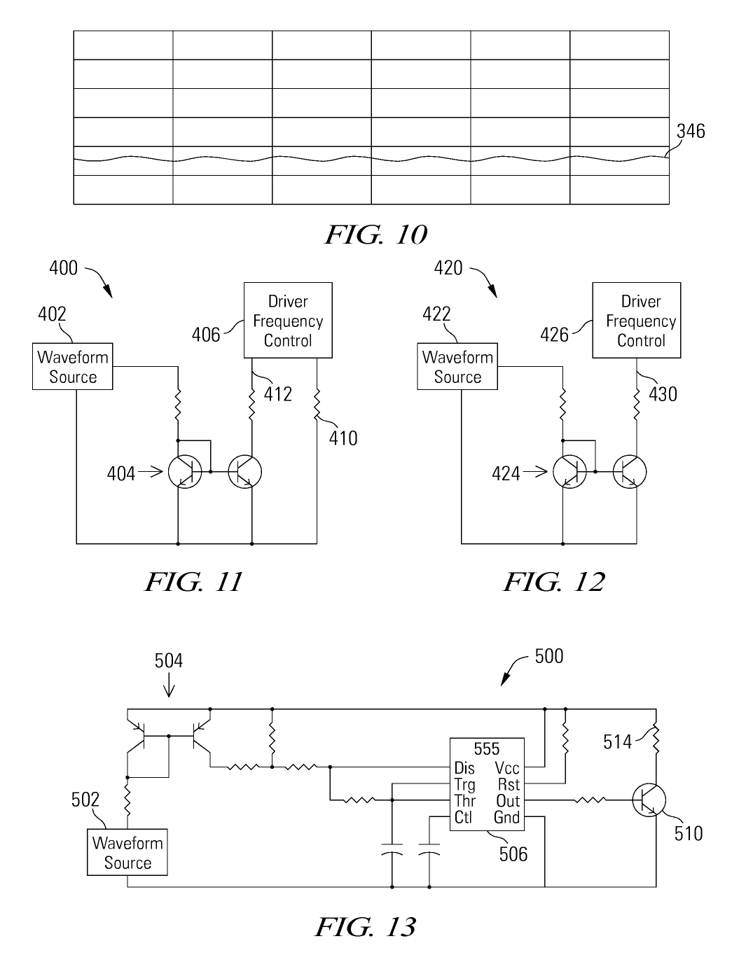

Turning to FIG. 8, dither circuit 300 is connected with output resistor 314 in parallel with external frequency control resistor 150. A small test resistor 336 is included to illustrate current waveforms at various circuit nodes. In FIG. 9, the constant current 344 across resistor 150 is illustrated. In FIG. 10, the modulated current 346 at node 338 between test resistor 336 and voltage source 334 is illustrated, or the total current including the modulated current from dither circuit 300 through resistor 314 and the constant current through resistor 150.

Turning to FIG. 11, a dither circuit 400 is depicted including a waveform source 402 and current mirror 404, connected to a frequency control device 406 in parallel with a frequency control resistor 410. The waveform source 402 may comprise any suitable circuit or device to generate a modulated current at the output 412, with any suitable dithering waveform, from the triangle wave illustrated in FIG. 4 to other simple or complex waveforms with constant or varying frequency also including, but not limited to, pseudo-random, random, noise, noise of any kind and type, etc. . . . The frequency control device 406 may comprise a portion of a variable pulse generator 134 in a dimming driver with dither circuit 100, for example, used to apply a voltage and to set the frequency of output pulses based on the resulting current.

Turning to FIG. 12, a dither circuit 420 is depicted including a waveform source 422 and current mirror 424, connected to a frequency control device 426 in place of or in series with or an external frequency control resistor. The waveform source 422 may comprise any suitable circuit or device to generate a modulated current at the output 430, with any suitable dithering waveform, from the triangle wave illustrated in FIG. 4 to other simple or complex waveforms with constant or varying frequency including, but not limited to, any pseudo-random, random, noise, etc. types. The frequency control device 426 may comprise a portion of a variable pulse generator 134 in a dimming driver with dither circuit 100, for example, used to apply a voltage and to set the frequency of output pulses based on the resulting current.

In other applications, the variable resistance circuit may be used in or incorporate or be incorporated into, for example but not limited to, noise sources, waveform generators (i.e., triangle, sine, sawtooth, pulse, square, AM, FM, etc. and combinations of these waveforms), semiconductor-based noise sources, microcontrollers, microprocessors, field programmable gate arrays (FPGAs), complex logic devices (CLDs), application specific integrated circuits (ASICs), analog and digital circuits and logic, shift registers, and may include pickups or sensors of RF and other EM, audible noise, mechanical and vibration noise, optical and photo input, etc. and any combinations of these.

The variable resistance circuit can be used as an “add on” feature to existing circuits, ICs, clocks, etc, and can have multiple embodiments of the present invention on the same circuit, sub circuit, subsystem, system, product, etc.

The variable resistance can be used for/with, for example, (but not limited to) power supplies, lighting including general lighting, light emitting devices (LEDs) and/or organic LEDs (OLEDs), fluorescent lighting, high intensity drivers, ballasts, power supplies, etc., communications, control electronics including lighting control, general electronics, etc. The variable resistance can be smart, intelligent, adaptable, programmable, etc. The variable resistance can used with discontinuous conduction mode (DCM), continuous conduction mode (CCM), critical conduction mode (CRM), resonant conduction mode, Cuk, SEPIC, etc. The variable resistance circuit can be used where voltage of the resistor (timing) element may be unknown or changing, etc.

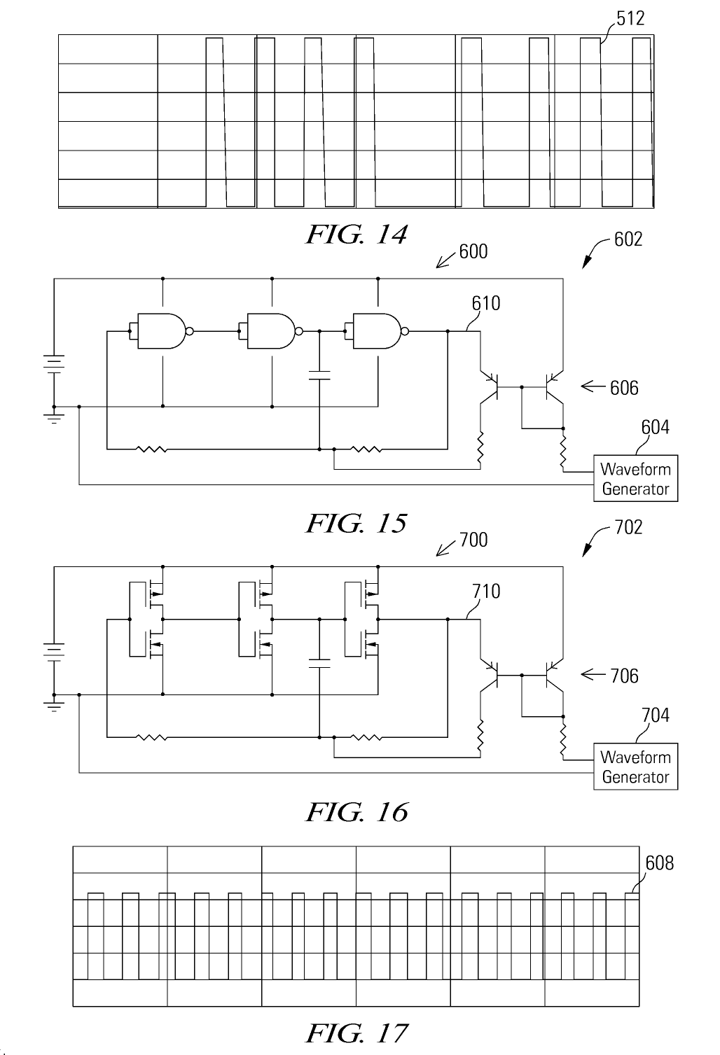

Turning to FIG. 13, a pulse generator with dither circuit 500 is depicted including a waveform source 502 connected through a current mirror 504 to a pulse generator 506, in this case a 555 timer. The pulse generator 506 is used to control a power control switch 510. A load 514 and main power input may be connected in series with the power control switch 510, with load 514 used to set the effective impedance of the frequency input (also referred to herein as an impedance input) to the pulse generator (e.g., 134). Load 514 may be connected alone to the frequency input of the pulse generator (e.g., 134), or in parallel or in series with an external resistor (e.g., 150) connected to the frequency input of the pulse generator (e.g., 134). Alternatively, power control switch 510 may correspond with output driver 30 in dimming driver 10. The pulse generator and dither circuit 500 may be adapted to generate a current waveform 512 such as that illustrated in FIG. 14 at the control input 514 of power control switch 510. Notably, current waveform 512 has a varying frequency caused by the dithering circuit including the waveform source 502 and current mirror 504.

Turning to FIG. 15, a NAND-based pulse generator 600 (which also may be made of other digital and related elements including, but not limited to, inverter-based, NOR-based, or other logic gate based pulse generator, etc.) is depicted with a dither circuit 602 including a waveform generator 604 and a current mirror 606. A variable frequency square wave 608 as illustrated in FIG. 17 is generated at output node 610, which may be used to control a power control switch such as output driver 30 of dimming driver 10 or switch 120 of dimming driver with 100.

Turning to FIG. 16, an inverter-based pulse generator 700 is depicted with a dither circuit 702 including a waveform generator 704 and a current mirror 706. The variable frequency square wave 608 as illustrated in FIG. 17 may be generated at output node 710, which may be used to control a power control switch such as output driver 30 of dimming driver 10 or switch 120 of dimming driver with 100. (Although subtle, the frequency of square wave current waveform 608 varies, and dither circuits 602 and 702 may be adapted to vary the frequency to any extent desired.) Furthermore, current waveform 608 may be any waveform including, but not limited to, for example a triangle wave, random wave, noise, sine, sawtooth, etc.

The present invention can be used in high power factor (PF) circuits with or without dimming including triac, forward and reverse dimmers, 0 to 10 V dimming, powerline dimming, wireless and other wired dimming, DALI dimming, PWM dimming, DMX, etc., as well as any other dimming and control protocol, interface, standard, circuit, arrangement, hardware, etc.

The example embodiments disclosed herein illustrate certain features of the present invention and not limiting in any way, form or function of present invention. Note that linear or switching voltage or current regulators or any combination can be used in the present invention and other elements/components can be used in place of the diodes, etc. The present invention can also include passive and active components and circuits that assist, support, facilitate, etc. the operation and function of the present invention. Such components can include passive components such as resistors, capacitors, inductors, filters, transformers, diodes, other magnetics, combinations of these, etc. and active components such as switches, transistors, integrated circuits, including ASICs, microcontrollers, microprocessors, FPGAs, CLDs, programmable logic, digital and or analog circuits, and combinations of these, etc. and as also discussed below.

The present invention can be used in power supplies, drivers, ballasts, etc. with or needing high power factor (PF) and/or lower THD circuits with or without dimming including triac, forward and reverse dimmers, 0 to 10 V dimming, powerline dimming, wireless and other wired dimming, DALI dimming, PWM dimming, DMX, etc., as well as any other dimming and control protocol, interface, standard, circuit, arrangement, hardware, etc.

The present invention is, likewise, not limited in materials choices including semiconductor materials such as, but not limited to, silicon (Si), silicon carbide (SiC), silicon on insulator (SOI), other silicon combination and alloys such as silicon germanium (SiGe), etc., diamond, graphene, gallium nitride (GaN) and GaN-based materials, gallium arsenide (GaAs) and GaAs-based materials, etc. The present invention can include any type of switching elements including, but not limited to, field effect transistors (FETs) such as metal oxide semiconductor field effect transistors (MOSFETs) including either p-channel or n-channel MOSFETs, junction field effect transistors (JFETs), metal emitter semiconductor field effect transistors, etc. again, either p-channel or n-channel or both, bipolar junction transistors (BJTs), heterojunction bipolar transistors (HBTs), high electron mobility transistors (HEMTs), unijunction transistors, modulation doped field effect transistors (MODFETs), etc., again, in general, n-channel or p-channel or both, vacuum tubes including diodes, triodes, tetrodes, pentodes, etc. and any other type of switch, etc. The present invention can, for example, be used with continuous conduction mode (CCM), critical conduction mode (CRM), discontinuous conduction mode (DCM), etc., of operation with any type of circuit topology including but not limited to buck, boost, buck-boost, boost-buck, cuk, etc., SEPIC, flyback, etc. In addition, the present invention does not require any additional special isolation or the use of an isolated power supply, etc. The present invention applies to all types of power supplies and sources and the respective power supply(ies) can be of a constant frequency, variable frequency, constant on time, constant off time, variable on time, variable off time, etc. Other forms of sources of power including thermal, optical, solar, radiated, mechanical energy, vibrational energy, thermionic, etc. are also included under the present invention. The present invention may be implemented in various and numerous forms and types including those involving integrated circuits (ICs) and discrete components and/or both. The present invention may be incorporated, in part or whole, into an IC, etc. The present invention itself may also be non-isolated or isolated, for example using a tag-along inductor or transformer winding or other isolating techniques, including, but not limited to, transformers including signal, gate, isolation, etc. transformers, optoisolators, optocouplers, etc.

The present invention can be used with a buck, a buck-boost, a boost-buck and/or a boost, flyback, or forward-converter design etc., topology, implementation, etc.

Other embodiments can use comparators, other op amp configurations and circuits, including but not limited to error amplifiers, summing amplifiers, log amplifiers, integrating amplifiers, averaging amplifiers, differentiators and differentiating amplifiers, etc. and/or other digital and analog circuits, microcontrollers, microprocessors, complex logic devices, field programmable gate arrays, etc.

The present invention includes other implementations that contain various other control circuits including, but not limited to, linear, square, square-root, power-law, sine, cosine, other trigonometric functions, logarithmic, exponential, cubic, cube root, hyperbolic, etc. in addition to error, difference, summing, integrating, differentiators, etc. type of op amps. In addition, logic, including digital and Boolean logic such as AND, NOT (inverter), OR, Exclusive OR gates, etc., complex logic devices (CLDs), field programmable gate arrays (FPGAs), microcontrollers, microprocessors, application specific integrated circuits (ASICs), etc. can also be used either alone or in combinations including analog and digital combinations for the present invention. The present invention can be incorporated into an integrated circuit, be an integrated circuit, etc.

While detailed descriptions of one or more embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. An apparatus for powering a load, comprising:
a power input;
a load output;
a switch operable to control a flow of current from the power input to the load output;
a power storage device operable to store power from the power input when the switch is closed and to release the power when the switch is open;
a pulse generator operable to open and close the switch based at least in part on an impedance value at an impedance input to the pulse generator; and
a dither circuit connected to the impedance input to the pulse generator and operable to vary the impedance value.

2. The apparatus of claim 1, wherein the dither circuit is operable to provide a variable resistance at the impedance input to the pulse generator.

3. The apparatus of claim 1, wherein the dither circuit is operable to dither a frequency of the pulse generator.

4. The apparatus of claim 1, wherein the impedance input comprises a frequency control input, and wherein the pulse generator is operable to control a frequency of a control signal used to open and close the switch based at least in part on the frequency control input.

5. The apparatus of claim 1, wherein the pulse generator comprises a variable pulse generator.

6. The apparatus of claim 1, wherein the power storage device comprises an inductor connected in series with the load output, further comprising a diode connected in parallel with the load output and the inductor and operable to provide a current loop when the switch is opened.

7. The apparatus of claim 1, further comprising a resistor connected to the impedance input to the pulse generator.

8. The apparatus of claim 1, further comprising a load current detector operable to detect a current through the load output, wherein the pulse generator is operable open and close the switch based at least in part on the load current detector.

9. The apparatus of claim 8, further comprising a reference current generator operable to provide a reference current to the load current detector, wherein the load current detector is operable to compare the current through the load output with the reference current.

10. The apparatus of claim 8, wherein an output of the load current detector is based in part on a dimming condition.

11. The apparatus of claim 1, wherein the dither circuit comprises a current mirror and resistor, wherein the resistor is connected to the impedance input to the pulse generator, and wherein the current mirror controls the current through the resistor.

12. The apparatus of claim 11, wherein the dither circuit further comprises:
an integrator operable to integrate an input signal to the integrator over time;
a comparator operable to switch the direction of integration of the integrator, wherein an output of the integrator drives the current mirror.

13. The apparatus of claim 11, wherein the dither circuit further comprises a waveform source operable to generate a waveform signal to the current mirror.

14. The apparatus of claim 13, wherein the waveform source is operable to generate a random waveform.

15. The apparatus of claim 13, wherein the waveform source is operable to generate a pseudo-random waveform.

16. The apparatus of claim 13, wherein the waveform source is operable to generate a noise waveform.

17. The apparatus of claim 13, wherein the dither circuit further comprises an oscillator operable to control the switch based at least in part on the current through the resistor.

18. The apparatus of claim 1, wherein the dither circuit comprises a waveform generator, a current mirror and resistor, wherein the resistor is operable to provide an impedance to the impedance input of the pulse generator, and wherein the current mirror controls the current through the resistor, the dither circuit further comprising a logic gate based pulse generator operable to provide a current source for an output of the current mirror.

19. The apparatus of claim 18, wherein the logic gate based pulse generator comprises a series of logic gates selected from a group consisting of: NAND gates, NOR gates, and inverters.

20. A method of powering a load, comprising:
generating a pulse stream in a pulse generator;
controlling a switch with the pulse stream to control a flow of current from a power input to a load output;
storing power from the flow of current when the switch is closed and releasing stored power to the load output when the switch is open; and
dithering a frequency of the pulse stream.
